(19) United States
(12) Patent Application Publication
(10) Pub. No.: US 2023/0243980 A1
(43) Pub. Date: Aug. 3, 2023

(54) Electromagnetic Survey System And Methods of Surveying Using Such

(71) Applicant: Groundwater Imaging Pty Ltdau, Dubbo (AU)

(72) Inventors: David Allen, Dubbo (AU); Edward Hribar, Dubbo (AU)

(21) Appl. No.: 18/162,360

(22) Filed: Jan. 31, 2023

(30) Foreign Application Priority Data
Jan. 31, 2022 (AU) 2022900175

(51) Int. Cl. G01S 19/14; G01R 33/34; G01S 19/35; G01V 3/12; G01V 3/15

(52) U.S. Cl. CPC G01S 19/14; G01R 33/34084; G01S 19/35; G01V 3/12; G01V 3/15

(57) ABSTRACT

Described embodiments generally relate to an electromagnetic survey system configured for geophysical prospecting comprising a structure of booms and rigging that supports and, during normal operation self-levels, a horizontal transmitter coil configured to transmit a magnetic moment. One or more receiver coils, mounted either centrally in the structure, at an extremity of the structure or independent of the structure receive signal from the ground that has been created by the transmitter coil by phenomenon and procedure known to geophysical prospecting practitioners. The structure is supported by a means of locomotion such as shoulders of walking persons, or a towed cart structure.

### TECHNICAL FIELD

The present disclosure relates to a field of geophysical prospecting, and more specifically, to a method and apparatus for conduct of electromagnetic survey. Specifically, described embodiments relate to a system that can be moved across the ground collecting data used to image substrate electrical resistivity.

### BACKGROUND

Geophysical prospecting by application of electromagnetic (EM) surveys where a primary electromagnetic field is generated to induce a secondary electromagnetic field in an underground formation has become widespread. Such prospecting has been achieved by laying coils of wire on the ground, transmitting into those coils and measuring ground response using receiver coils. The whole system is then moved to another site and the process repeated until data for a whole transect or map is collected. Many applications such as mineral exploration are viable using such a procedure but for most hydrogeological and geotechnical applications, such as siting bores or mapping differences in sediment below the surface that affect groundwater recharge, such a procedure is typically too costly.

A structure that facilitates efficient carriage of a large coil of wire, and supporting electronics across undulating terrain, is advantageous to such applications of geophysics. When electromagnetically imaging tens of meters into the earth, a coil of similar dimensions to the exploration depth is advantageous but large coils are not readily carried across the ground surface. To some extent the coil size can be diminished, compensating by increasing transmitted current or receiver sensitivity but, even then, coil dimensions can remain problematically large for moving across the ground continuously.

Further, as separation of the transmitter coil and receiver coil is diminished, there is an increase in direct interference between the transmitter coil and receiver coil. When both are on the same structure, they must be close. Improvement in the dynamic range of receiver electronics in recent years has made it possible to make use of data from systems with closer coils.

There remains a need for a practical means of carriage of such coils across terrain as continuous acquisition occurs. Such a structure must be able to, on occasions, pass through narrow gaps such as gateways or between trees. Such gaps often are much narrower than the width of practical electromagnetic transmitter coils. It is easy to make a support vehicle with a wheel separation, or should it be walking persons, a foot separation, that is sufficiently narrow to pass through narrow gaps but narrow support separation results in increased tilting of such vehicles as they pass over laterally undulating ground such as tussock covered land. This is especially so with wheeled vehicles, many of which contain stabilizer bars that further accentuate the problem. If large coils are placed on such vehicles, then tilting amplifies direction change forces at sides of those coils to the eventual point that the support structure is violently broken by large abrupt changing forces. Additionally, electromagnetic induction occurs in the coils as they are violently moved through the magnetic field of the earth. This unwanted induction adds to noise when detecting signals from the coils.

Any discussion of documents, acts, materials, devices, articles or the like which has been included in the present specification is not to be taken as an admission that any or all these matters form part of the prior art base or were common general knowledge in the field relevant to the present disclosure as it existed before the priority date of each of the appended claims.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### Background Electromagnetic Theory

EM systems can be either frequency-domain or time-domain. Both types of systems are based on principles encapsulated in Faraday's Law of electromagnetic induction, which states that a time-varying primary magnetic field will produce an electric field. For typical continuous survey systems, the primary field is created by passing a current through a transmitter coil. The temporal changes to the created or radiated magnetic field induce electrical eddy currents in the ground. These currents have an associated secondary magnetic field that can be sensed, together with the primary field, by a series of receiver coils. Each receiver coil may consist of a series of wire coils, in which a voltage is induced proportional to the strength of the secondary electromagnetic field from the eddy currents in the ground and their rate of change with time. Coils with their axes in the same direction as the transmitter coil axis are most sensitive to horizontal layers and half-spaces if the transmitter coil is horizontal. Coils with their axes orthogonal to the horizontal ground are most sensitive to discrete or vertical conductors.

For time-domain systems, a time-varying field is created by a current that may be pulsed. The change in the transmitted current induces an electrical current in the ground that persists after the primary field is turned off. Typical time domain receiver coils measure the rate of change of decay of this secondary field. The time-domain transmitter current waveform repeats itself periodically and can be transformed to the frequency domain where each harmonic has a specific amplitude and phase.

### Background Pendulum Theory

Electromagnetic survey systems typically use large coils of wire to make it possible to detect substrate heterogeneity at as great a depth as is possible. When placed on moving vehicles, any tilting of the vehicle due to movement over rough ground, can create greatly amplified movement at the extremities of the coil if the coil is rigidly fixed to the vehicle. In contrast, if it is attached in the form of a pendulum then tilting forces need not be transferred to the supported coil.

A pendulum, under the influence of gravity, is a body that may rotate around an axis and that has a centre of gravity that is not exactly on the axis of rotation. It is also subject to gravitational force such that it swings back and forth after being perturbed from a position directly beneath the axis of rotation. The frequency of rotation is affected by the ratio of the product of the centre of mass with its separation distance from the axis of rotation and with the radius of gyration of the body about the rotation axis. Radius of gyration is defined as the radial distance to a point which would have a moment of inertia the same as the body's actual distribution of mass, if the total mass of the body were concentrated there. Mathematically the radius of gyration is the root mean square distance of the object's parts from a given axis.

A pendular body will have a low frequency of oscillation when the distance from the centre of gravity of that body to an axis around which it is permitted to rotate is small compared to its radius of gyration about that same axis.

### SUMMARY

Some embodiments relate to a device for measuring electromagnetic (EM) signals for mapping subsurface structures, the device comprising: a survey EM transmitter for generating survey EM signals and/or a survey EM receiver for receiving and recording survey EM signals; a support structure; and a wire, mounted to the support structure, the wire configured to transmit EM signals generated by the survey EM transmitter and/or receive EM signals received by the survey EM receiver; wherein when the device is in use, the center of gravity of the support structure is between an axis of rotation of the support structure and the ground, such that movement of the wire is substantially dampened.

In some embodiments, the support structure comprises: a first support member; and a second support member pivotably connected to the first support member; wherein the second support member is moveable between a first position and a second position.

In some embodiments, when the device is in use and when the second support member is in the first position, the second support member is substantially parallel to the ground; and when the second support member is in the second position, the footprint of the device is reduced.

In some embodiments, the wire is mounted to a distal end of the first support member and a distal end of the second support member.

Some embodiments may comprise a third support member, mounted to the first support member, wherein when the device is in use, the third support member is orientated substantially perpendicular to the ground.

Some embodiments may comprise a rope, connected to the second support member and running through a pulley mounted on the third support member; wherein the rope is configured to move the second support member from the first position to the second position.

Some embodiments may comprise a first wire mounting member mounted to a distal end of the first support member and a second wire mounting member mounted to a distal end of the second support member, and wherein the wire is mounted to the first wire mounting member and the second wire mounting member.

Some embodiments comprise a set of wheels, the set of wheels configured to allow the device to be pulled along the ground when in use.

In some embodiments, the support structure comprises telescopic members.

Some embodiments are configured to be carried by one or more human operators while in use.

In some embodiments, the set of wheels is mounted to a second support structure; and wherein the second support structure is configured to be attached to a powered vehicle.

In some embodiments, the powered vehicle is a car or a tractor.

Some embodiments comprise a substrate nuclear magnetic resonance detection system utilizing the magnetic field of the earth as its background field.

Some embodiments comprise a global navigation satellite system (GNSS) positioning device.

Some embodiments comprise rigging for giving additional structural rigidity to the support structure.

In some embodiments, the wire is a first wire, and the first wire is configured to transmit survey EM signals; and wherein the device further comprises a second wire, the second wire configured to receive EM signals induced in subsurface structures.

Some embodiments comprise two second support members, wherein the two second support members are pivotably connected to opposite sides of a portion of the first support member, the portion being substantially equidistant between two end points of the first support member.

In some embodiments, wherein when the two second support members are in the first position, the wire forms a substantially oval-like shape.

In some embodiments the wire is a cable of one or more insulated conductors, or a wire loop of one or more turns.

Some embodiments relate to a method of mapping a substrate using the device of any of the described embodiments, the method comprising: inducing, in a subsurface structure to be mapped, an electrical current using the EM transmitter and the first wire; recording, using the EM receiver and the second wire, the induced electrical current in the subsurface structure to be mapped.

Some embodiments relate to a method of mapping a substrate using the device of any of the described embodiments, the method comprising: positioning a receiver coil on an area of ground to be surveyed; inducing, using the survey EM transmitter and the wire, an electrical current in a subsurface structure to be mapped; recording, using the receiver coil and the survey EM receiver, change in the electrical current in the subsurface structure

Some embodiments of the present disclosures relate to an electromagnetic survey system configured for geophysical prospecting comprising a structure that supports and, during normal operation self-levels, a horizontal transmitter coil configured to transmit a magnetic moment. One or more receiver coils mounted either centrally in the structure, at an extremity of the structure or independent of the structure receives signal from the ground that has been created by the transmitter coil by phenomenon and procedure known to geophysical prospecting practitioners. In some embodiments of the present disclosures, the transmitter coil is suspended from tips of a set of booms. One longitudinal boom extends the length of the structure, and one or more pairs of lateral booms pivot off bodies placed along the length of the main boom. Posts extending vertically off those bodies suspend the pivoted lateral boom pairs either directly through rigging ropes or via a pivoting fixture connected to rigging ropes in such a manner that the centre of gravity of the structure routinely is below the axis of the longitudinal boom. When the longitudinal boom is supported by a means of locomotion such as shoulders of walking persons, or a towed cart structure, then the coil self-levels as it travels.

Additional rigging, which may be the transmitter or receiver coils themselves, keeps the lateral booms in their horizontal position.

Rigid sections of the otherwise flexible, suspended transmitter coil, bisected by the points of suspension can increase the size of coil area with respect to suspension structure dimensions and weight.

Additional rigging attached to lateral booms via kite blocks can be used to lift lateral boom pairs and the transmitter coil to allow the entire structure to pass through narrowgaps.

More generally, some embodiments of the present disclosures comprise structures suspended from or supported by moving vehicles in such a way that they may pivot, in a damped manner around an axis passing through the points of support. Those structures incorporate transmitting and receiving coils, typically of size that is much larger than the width of supports of the vehicles such as wheels or feet (should the vehicle be walking persons). Those coils need to be kept stable partly simply to make carrying them efficient, and partly because they detect movement related electromagnetic noise if they are tilted violently and abruptly. If they are carried with their centre of gravity just slightly below the axis of support and with radius of gyration, about that same axis, of much greater distance then violent movement of the vehicle is transferred to the self-levelling structure in a very damped manner and such that violent rotational forces do not develop such that strong heavy construction is not required.

### BRIEF DESCRIPTION OF DRAWINGS

To clearly illustrate the technical solution of the embodiments of the present disclosure or in the prior art, the drawings that should be utilized in the description of the embodiments or the prior art are briefly described in the following; it is understood that the described drawings are only related to some embodiments of the present disclosure; based on the drawings, those ordinarily skilled in the art can acquire other drawings without any inventive work.

Coil is defined, in the context of this document, as a loop of electrically insulated, electrically conductive wire of arbitrary cross section shape, and of one or more turns, wherein the end of each turn, apart from the last turn, is electrically connected to the beginning of the subsequent turn. The beginning of the first turn and the end of the last turn then form a pair of wires that may be connected across terminals of electrical equipment such as transmitters or receivers.

The accompanying drawings, which are incorporated in and constitute a part of the specification, illustrate one or more embodiments and, together with the description, explain these embodiments. In the drawings:

FIG. 1 is a perspective view of an embodiment of the EM system being supported by two persons in the normal survey attitude;

FIG. 2 is a perspective view of an embodiment of the EM system being carried by two persons with the transmitter coil folded vertically to allow the system to pass through narrow gaps;

FIG. 3 is a perspective view of an embodiment of the EM system being supported by a largely non-metallic towed cart;

FIG. 4 is a top view of an embodiment of a ball and socket pivot on a lateral boom;

FIG. 5 is a perspective view looking obliquely from above and the front left of an abstract schematic representation of a structure connected to a moving vehicle in which that structure has a centre of gravity slightly under the axis of connection and a radius of gyration, of much greater separation around that same axis;

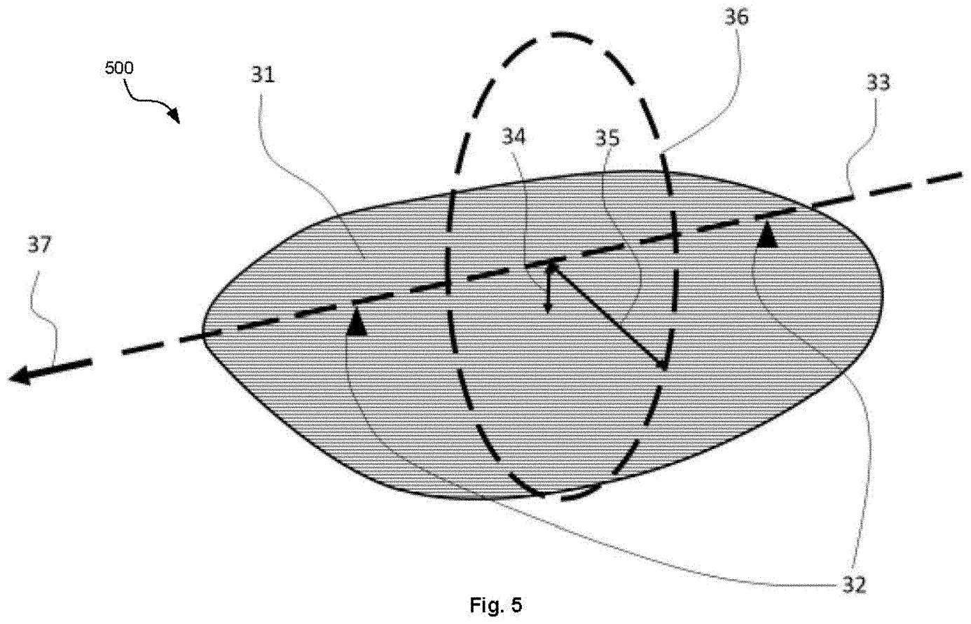

FIG. 6 is a perspective view looking obliquely from above at the front right of a receiver coil supported in a stable manner in front of a towing vehicle;

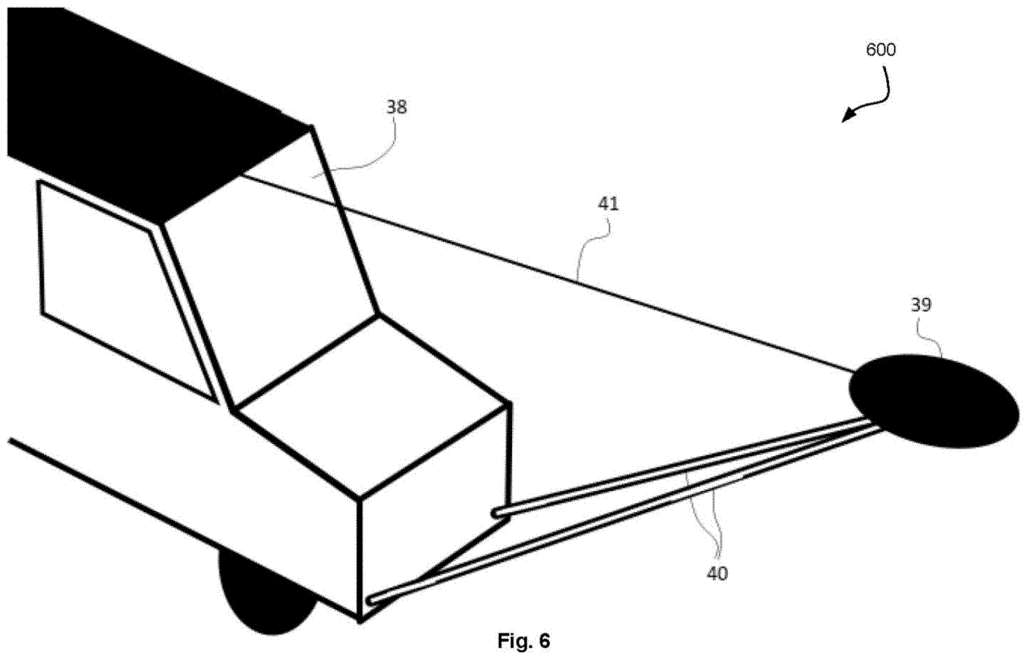

FIG. 7 is a front view (looking along the axis of the longitudinal boom (1)) zoomed in on attachments to one embodiment of a central post (4) extending upward from the longitudinal boom of an embodiment of the EM system. In this embodiment a pivoting bracket (44) facilitates damped self-levelling, in the plane perpendicular to the longitudinal boom, of the EM coil supported by rigging and booms; and

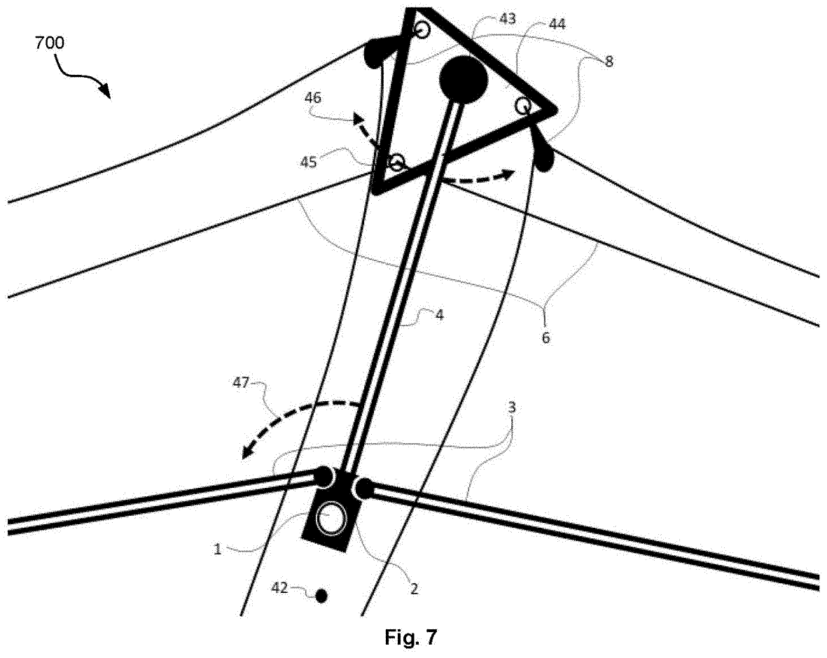

FIGS. 8A and 8B are plan views of embodiments without, and with, wire mounting members, respectively, according to some embodiments.

Numbers on the drawings refer to the respective features in the following table:

| Number | Feature |
|---|---|
| 1 | Longitudinal boom |
| 2 | Central block with sockets from which lateral booms pivot |
| 3 | Pair of pivoting lateral booms |
| 4 | Upper vertical post extending from (2) |
| 5 | Transmitter coil |
| 6 | Pair of lateral boom suspenders |
| 7 | Roll opposing lever |
| 8 | Pair of ropes and kite blocks for lifting the pair of lateral booms |
| 9 | Central horizontal receiver coil doubling as optional additional horizontal rigging |
| 10 | Longitudinal vertical plane upper support ropes |
| 11 | Longitudinal vertical plane lower support post and ropes |
| 12 | Means of support and locomotion of the structure (1st person) |
| 13 | Means of support and locomotion of the structure (2nd person) |
| 14 | Rigid spar, with midpoint suspender, fixed along part of the transmitter coil (back) |
| 15 | Rigid spar, with midpoint suspender, fixed along part of the transmitter coil (front) |
| 16 | Rigid spar, with midpoint suspender, fixed along part of the transmitter coil (right) |
| 17 | Rigid spar, with midpoint suspender, fixed along part of the transmitter coil (left) |
| 18 | Levelling spar suspender and weak link attached to each boom tip |
| 19 | Supporting structure with wheels |
| 20 | Pair of wheels of largely non-metallic construction (pneumatic, flexible urethane |
| | donuts on rigid hubs) |
| 21 | Drawbar |
| 22 | Drawbar rigging applying tension between the towing hitch coupler and the |
| | wheels. |
| 23 | Towing hitch coupler |
| 24 | Obstacle deflector |
| 25 | Deflection absorbers/dampers which limit yaw and pitch between the |
| | drawbar and the platform (19) |
| 26 | Re-routing of (8) down to and along the drawbar to the towing vehicle |
| 27 | A socket within the central pivot block (2) |
| 28 | A ball terminating one of a pair of lateral booms (3) |
| 29 | A pair of elastic coils retaining the ball (28) within the socket (27) |
| 30 | A sleeve, with hooks attached over which elastic coils (29) are stretched, |
| | which is fixed around a boom |
| 31 | Schematic representation of a structure incorporating a wire coil |
| 32 | Connection points of a vehicle to structure (31) |
| 33 | Axis passing through points of connection of structure (31) to a vehicle |
| 34 | Distance and vector orientation from axis (33) to the centre of gravity of |
| | structure (31) |
| 35 | The radius of gyration of structure (31) around axis (33) |
| 36 | Circumscription of the radius of gyration (35) in an arbitrary plane |
| | perpendicular to the axis (33) |
| 37 | The approximate direction of movement of the vehicle connected to the |
| | structure (31) |
| 38 | Towing vehicle |
| 39 | A structure supported near its centre of gravity and incorporating a receiver |
| | coil |
| 40 | A pair of booms joined at one end and pivoting, forward and upward, from |
| | the lower front extremities of towing vehicle (38) |
| 41 | Rope attached to the upper centre of towing vehicle (38) and to the join of |
| | booms (40) |
| 42 | The centre of gravity of the EM structure supported by connection points |
| | along the axis of the longitudinal boom (1) when the pair of lateral boom |
| | suspenders (6) are taut. |
| 43 | A pivot axis parallel to the axis of the longitudinal boom (1) passing through |
| | the point at the top of the upper vertical post (4) |
| 44 | A plate that pivots around the pivot axis (43) at the top of the upper vertical post (4) |
| | and via which rigging (6) and rigging (8) are attached to post (4). |
| 45 | A point in which rigging, comprising a pair of lateral booms suspenders (6), |
| | is attached via a pivoting plate to the top of the upper vertical post (4) |
| 46 | The possible path of rotation of rigging attachment point (45) around the |
| | top of vertical post (4) |
| 47 | Roll opposing force applied to the structure of booms (3), block (2), boom |
| | (1), central post (4) and coil (5), about the axis of the longitudinal boom, |
| | both by the non-radial orthogonal component of the vector force of the |
| | centre of gravity of the structure itself, and by a roll opposing lever (7). |

With reference to the feature list, the application discloses embodiments and combinations of embodiments from the listed items.

### DETAILED DESCRIPTION OF EMBODIMENTS

The following description of the exemplary embodiments refers to the accompanying drawings. The same reference numbers in different drawings identify the same or similar elements. The following detailed description does not limit the present disclosures. Instead, the scope of the disclosures are defined by the appended claims. Many of the following embodiments are discussed, for simplicity, with regard to the terminology and structure of an EM survey system with just one EM receiver coil, attached centrally. However, the embodiments to be discussed next are not limited to this configuration; they may have other receiver coils placed in alternative positions mentioned in the claims. Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

Specific embodiments of the present disclosures will be discussed first as examples for the more general, abstract description so that relevance of the general, abstract case is easier to understand. Then the general, abstract, fundamental description will be discussed.

The device 100 is configured for measuring electromagnetic (EM) signals for mapping subsurface structures, such as sub-surface geologic and/or hydrologic structures. In some embodiments, the present disclosures comprise a support structure, the support structure being configured to hold, in particular arrangement, a wire. The wire being configured to transmit and/or receive EM signals. For example, when configured to transmit, the wire may be caused to produce and/or otherwise generate EM waves to interact with subsurface structures and/or fluids. In some embodiments, when the wire is configured as a receiver, the wire may detect change in EM currents that have been induced in subsurface structures and/or fluids. In some embodiments, the present systems and methods comprise an EM transmitter and an EM receiver operable with the wire. In some embodiments, the wire may form a closed loop, such as being connected across the EM transmitter and/or EM receiver, and may be a cable of one or more insulated conductors, or a wire loop of one or more turns.

The support structure, of some embodiments, may comprise a first support member. The first support member may be an elongate pole, for example. In some embodiments, the support structure may comprise a second support member. The second support member may be an elongate pole of similar length and/or diameter to the first member or the second support member may be shorter than the first support member and/or have a different diameter. The second support member may be connected to the first support member, for example at a portion of the first support member, the portion being substantially equidistant between two end points of the first support member. In some embodiments, the support structure may comprise two or more second members.

In some embodiments, the second support member may be pivotably connected to the first support member, such that the second support member is pivotable between a first and second position. When in the first position, the second support member may be orientated substantially parallel to the ground, or otherwise parallel to the surface the device (100) is mapping the subsurface of, when the device (100) is in use. When in the second position, the footprint of the device 100 may be reduced. For example, the second support member may be lifted from their horizontal position to be substantially perpendicular to the ground, when the device is in use.

In some embodiments, the support structure comprises a third support member, connected to the first support member. The third support member may be perpendicular to the first support member and orientated vertically when the device (100) is in use. In other words, the third support member may be substantially perpendicular to the ground, or otherwise perpendicular to the surface the device (100) is mapping the subsurface of, when in use. In some embodiments, a rope may be connected to the second support member, the rope may also pass through a pulley mounted on the third support member, and configured to move the second support member between the first and second positions.

The support structure, in some embodiments, may comprise rigging, connected between two or more of the first, second and/or third support members. The rigging may be configured to reduce bending, twisting and/or deflection of the first support member, second support member and/or third support member, ether during transport or when in use. For example, the rigging may comprise a cable strung between a distal point of the third support member, to a point on the first support member or the second support member. When in use, the cable may be in a state of tension, as to resist bending, twisting and/or deflection of the support structure.

In some embodiments, disposed on each of the first support member and/or the second support member, is a wire mounting member. The wire mounting member may be more flexible than the support member, or equally as flexible or rigid as the first support member, and configured to arrange the wire in an optimal position for transmitting and/or receiving EM signals, such as by increasing the surface area covered by the wire, and/or absorbing movements of the wire while the device 100 is in use. The wire mounting members may, in some embodiments be substantially rigid members. In some embodiments, the wire mounting members may be disposed on each of the first support member and/or the second support member at a point that substantially bisects the length of the wire mounting members. The wire may be bound substantially along the length of the wire mounting member, such that the area encompassed by the wire in the form of a loop is increased without increasing the dimensions of each of the first support member and/or the second support member, nor substantially increasing the weight of the second support member or support structure overall.

In use, the device (100) may be lifted and/or carried by two or more human operators. For example, the device (100) may be placed upon the shoulders of the two or more human operators such that the device (100) may be carried over the ground that is being mapped. In some embodiments, the device (100) may comprise a set of wheels, configured such that the device (100) may be pulled, such as by the two or more operators. In some embodiments, the set of wheels may allow a single human operator to use the device (100) by pulling the device (100) rather than carry the device (100) on the shoulders of the two human operators.

In some embodiments, the set of wheels may be mounted to a second support structure. The second support structure may be configured to attach to a powered vehicle, so as to pull the device (100) over the ground to map the subsurface. The powered vehicle may be a car or a tractor, for example, or any other powered vehicle capable of traversing the terrain that is being mapped.

In some embodiments, the second support structure may be configured to be connected to and operable with an electrically powered all-terrain vehicle, such as the Cyber Clydesdale as manufactured by Curly's AG. Use of an electrically powered all-terrain vehicle, in combination with the configuration of the second support member to be moveable between the first and second position, may allow for the device (100) to be used on terrain and/or in locations that are particularly cramped and/or are particularly rugged.

According to some embodiments, the wire may be a first wire and may be configured to transmit survey EM signals and the device (100) may further comprise a second wire, configured to receive EM signals induced in subsurface structures.

In some embodiments, the support structure may comprise two second support members, pivotably mounted to opposite sides of the first support member. For example, the two second support members may be mounted to a portion of the first support member at a point substantially equidistant between two distal ends of the first support member.

Present disclosures also relate to methods of mapping a substrate using device (100). For example, the first wire may be used to induce EM currents in one or more subsurface structures, these EM currents may then propagate outwards and change in the magnetic field resulting from those currents can be received as induced voltage across the ends of the second wire. These received voltages from the subsurface structures can then be stored and interpreted to determine the structure and composition of the subsurface.

Another method for mapping a substrate using the device (100) may comprise placing a static receiver wire array on a portion of ground above the subsurface which is to be mapped. The device (100) may then be moved proximal to and/or over the static receiver wire array while the wire transmits EM waves. The static receiver wire array may then receive or otherwise detect the induced EM currents in the subsurface structures, so that the structure of the subsurface may be mapped.

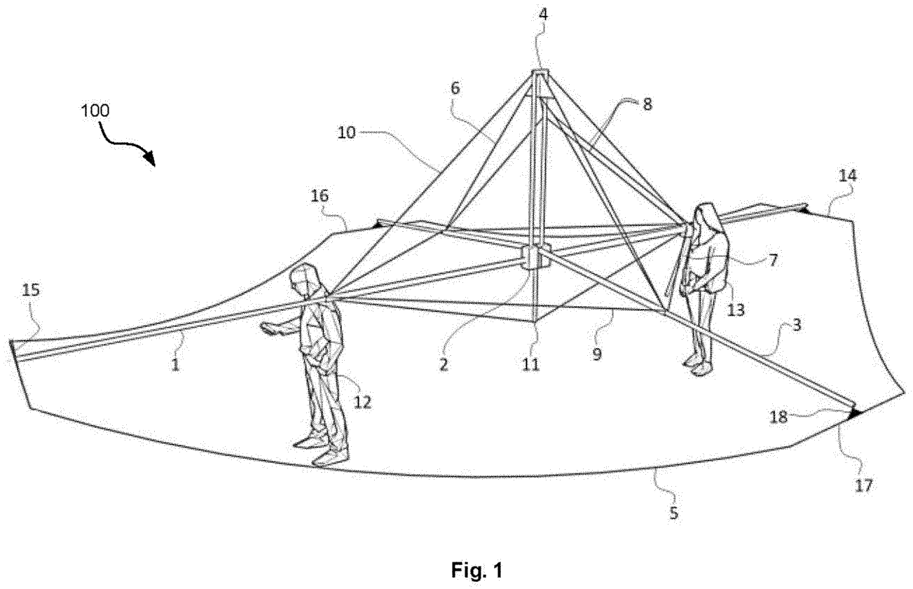

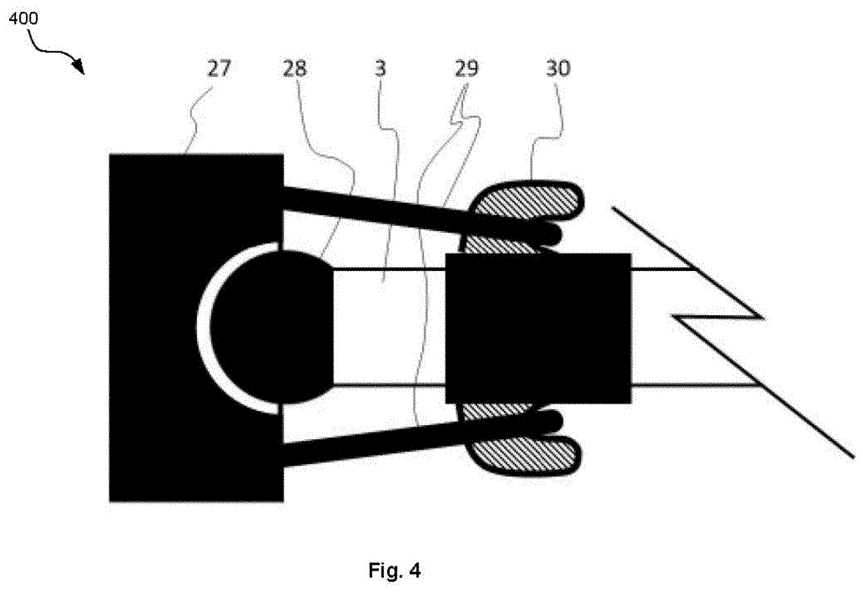

Referring now to the present systems and methods in more detail, in FIG. 1 there is shown an embodiment of the present disclosures in which fundamental parts of the device are present. There is a first support member, or longitudinal boom (1), upon which there is one central block (2) from which a pair of second members or lateral booms (3) pivot within a pair of sockets in the central block (2). FIG. 4 shows the top view of one of a pair of spherical balls (28), such as exists on the ends of each of the pair of lateral booms (3), recessed into the said pair of sockets (27) in such a way that these booms can pivot 10 degrees, horizontally, either way from perpendicular to the longitudinal boom as well as from 15 degrees below horizontal right up to substantially vertical. The pair of pivoting balls (28) of the pair of lateral booms are held in place by two pairs of elastic cord coils (29) fixed to the central block (27) and stretched over hooks protruding from opposite sides of sleeves (30) fitted over each of the pair of lateral booms.

Fixed within the central block (2) there is, extending upwards, a third support member or upper vertical post (4) for the fixture of rigging.

Attached to both tips of the longitudinal boom (1) and the non-pivoting tips of the pair of lateral booms (3) is the transmitter coil (5) which consists of one or more turns of insulated wire. At one longitudinal boom tip, flying leads extending from the coil pass to a transmitter.

Attached approximately midway along the pair of lateral booms is a pair of lateral boom suspending ropes (6) which also are attached to a fixture at the top of post (4) and have a length that limits suspension orientation, in the plane perpendicular to the longitudinal boom, of each of the pair of lateral booms to slightly below the horizontal plane containing the longitudinal boom (1) so that the centre of gravity of the whole structure is slightly below the level of the longitudinal boom (1) such that it is fundamentally stable when the longitudinal boom (1) is supported at points along its length.

In order to apply torque around the axis of the longitudinal boom, to said lateral booms, to deviate the orientation of any side of the transmitter coil (5) from substantially horizontal, the post (4) must be kept substantially vertical. This is achieved by applying force to the roll opposing lever (7) either whenever post (4) begins to deviate from vertical, or when a vehicle attached by the roll opposing lever tilts due to sideways tilting of said vehicle as it passes over undulating ground. In normal survey attitude no force is required because the centre of gravity is lower than the supported longitudinal boom but on occasions when booms are lifted, or they impact upon obstacles, a force will need to be applied to this lever (7) to keep the embodiment upright.

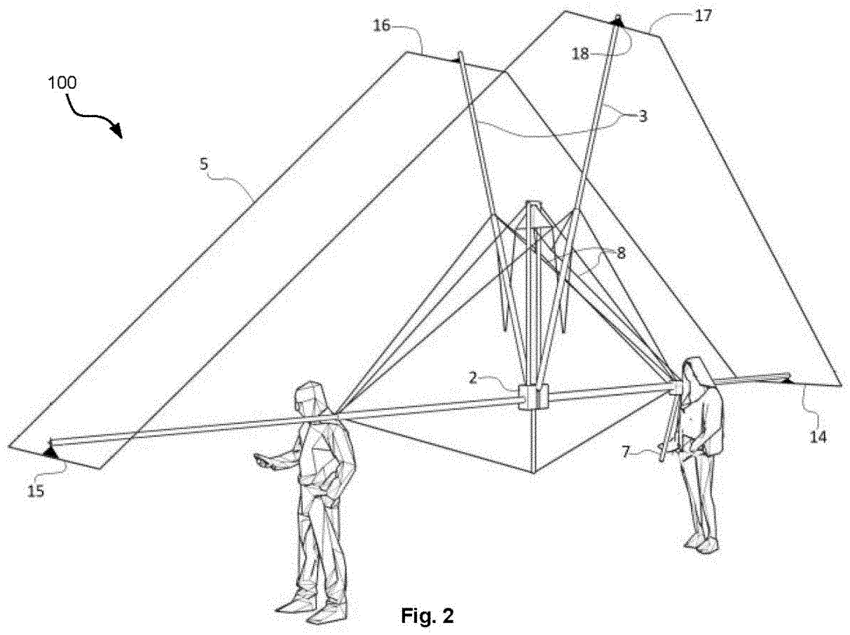

A pair of ropes (8), passing through kite pulley blocks attached to the top of the central vertical post (4), are attached approximately midway along each of the pair of lateral booms (3) and extend to where they can be pulled and released. This makes it possible to lift the pair of lateral booms (3) to a substantially vertical attitude such that the embodiment becomes narrow such that it can be moved through narrow gaps such as exist between close trees and within gateways. In FIG. 2. This embodiment is presented with the lateral booms raised in this manner. When the booms are raised, care is required to apply correcting forces to the roll opposing lever (7) to keep the now fundamentally unstable embodiment substantially in a vertical plane. If these correcting forces are not accurately and promptly applied then tipping forces will increase until force that must be applied to the lever is very large, should tipping of the whole structure be prevented.

In the embodiments in FIGS. 1, 2, and 3, a central horizontal receiver coil of one or more insulated turns (9) is fixed to approximately the midpoints of the pair of lateral booms (3) and to the 1st and 3rd quartile points of the longitudinal boom (1) such that it forms a rhombus. This embodiment of a receiver coil has the added advantages that:
it is centrally located so it provides substrate response from a most compact horizontal area of the substrate;
it is distanced from the transmitter coil (5) so as to reduce mutual inductance with the transmitter coil (5);
noise from movement of the coil through the magnetic field of the earth is a smaller proportion of received overall signal when coil dimensions are enlarged; and
it provides additional horizontal rigging which holds the lateral pair of booms (3) in place even when the transmitter coil (5) is detached which is useful during assembly and disassembly of the embodiment.

In the embodiments in FIGS. 1, 2, and 3, in the longitudinal vertical plane encompassing the longitudinal boom (1) and upper vertical post (4), there are, additional ropes attached to the top of the substantially vertical post (4), rigidly fixed above the central portion of the longitudinal boom (1), for the purpose of opposing bending forces on the central part of the longitudinal boom (1) when the pair of ropes (8) for lifting the pair of lateral booms are pulled.

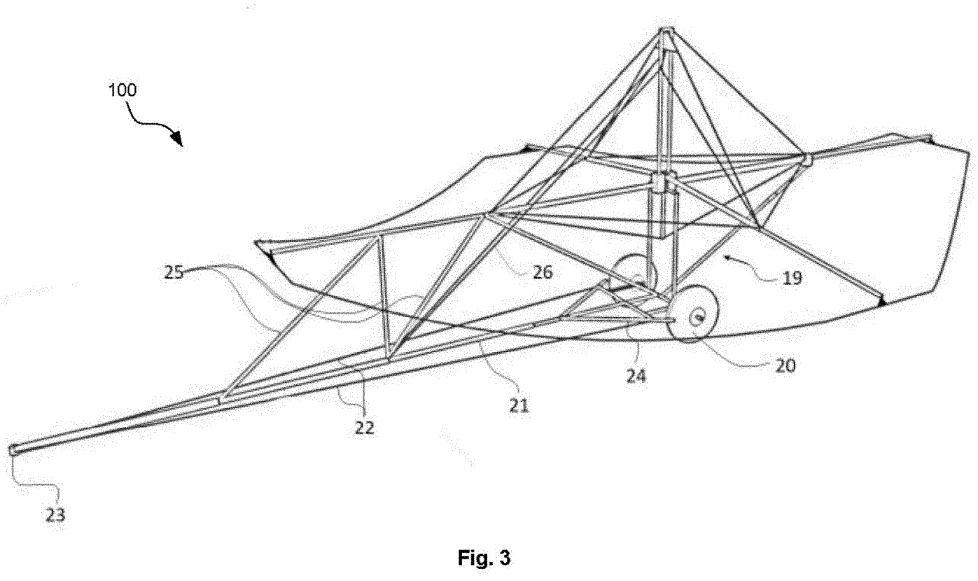

In the embodiments in FIGS. 1, 2, and 3, a longitudinal vertical plane lower support post and ropes (11) are fixed beneath the central portion of the longitudinal boom (1) for the purpose of opposing bending forces on the central part of the longitudinal boom (1) by the weight applied onto central pivot block (2) by the pair of lateral booms (3) and transmitter coil (5). In the embodiment in FIG. 3 this feature (11) is made redundant by supporting struts of the optional supporting structure with wheels (19), except in cases where the coil support structure may be transferred, and used, on and off the optional supporting structure.

In the embodiment in FIGS. 1 and 2, the means of support and locomotion of the structure is two persons (12) and (13) who are shown carrying the structure on their shoulders. In such an embodiment the supporting electronics may be carried either attached to the structure, in backpacks on the persons, or by a separate person attached by cables. The device, in another embodiment, can also be carried by a single person using one shoulder and their hands, or suspended, using a sling resting over one of their shoulders. In such an embodiment the supporting electronics may be carried separately, attached by cables. It is of additional benefit if there is a padded fixture placed on the persons' shoulders that prevents slippage of the structure off their shoulders when it is not held in place using their hands. When carrying the structure through rows of trees in orchards, ability to sling the structure at a height beneath the base of the canopy of the trees is beneficial as wider transmitter loops can then be walked along between those rows of trees.

In the embodiments in FIGS. 1 and 2 there are a four rigid spars of fiber reinforced polymer construction (14,15,16 & 17) or otherwise referred to as wire mounting members, with load levelling midpoint suspenders (18), fixed along the parts of the transmitter coil that span the attachment points such that they are each bisected by their respective attachment points. These spars (14,15,16, & 17), when attached to the tips of the booms of the device, permit the transmitter coil (1) to be more rounded rather than of simple rhombus shape. This greatly increases coil area and thus transmitted magnetic moment for the equivalent structure dimensions and weight. The attachment points (18) are flexible plastic cord spanning the midpoint of the spars with ends attached by glue coated poly-olefin tube that is heatshrunk over the transmitter coil cable. Attachment to the booms (1, 3) is by means of weak links (cable ties) that are easily replaced if broken during survey. Ends of these spars are attached to the cable using the same method. In this embodiment, this results in a transmitter coil (1) that self-levels and absorbs, damps and distributes impacts on the structure around the entire transmitter coil (1). Sufficient catenary slack must be left in the transmitter coil for it to be folded upwards without bending the booms unduly.

FIG. 3 shows an embodiment of the present disclosures supported by a secondary or wheeled structure (19). The wheeled structure consists of:
rods and brackets connecting the roll opposing lever (7), central pivot block (2) and longitudinal boom (1) to an axle housing and axle positioned substantially beneath the centre of gravity of the structure;
a pair of wheels of largely non-metallic construction (very low pressure pneumatic, flexible urethane) (20);
a drawbar (21) fixed near the centre of the axle housing and extending sufficiently beyond the transmitter coil (1) to allow a metallic towing vehicle to tow the structure, with manageably small inductive coupling between itself and the transmitter coil (1);
a towing hitch coupler (23);
drawbar rigging (22) which applies tension between the towing hitch coupler (23) and the wheels so as to keep the drawbar substantially perpendicular to the axle and so as to more directly transmit forces of impacts to the wheels to the towing hitch coupler;
an obstacle deflector (24); and
deflection absorbers/dampers (25) which limit yaw and pitch between the drawbar and the platform (19).

When the wheeled support structure (19) is used, re-routing (26) of the pair of ropes and kite blocks, used for lifting the pair of lateral booms (8), is necessary, down to and along the drawbar to the towing vehicle drawbar.

The centre of gravity of said supported structure should be slightly behind the axle of the wheeled support structure (19) such that the pitch and yaw limiting deflection absorbers/dampers are normally in tension such that the supported structure will self-correct to alignment with its longitudinal boom parallel to and directly above the drawbar.

Embodiments of the present disclosures may be used with various combinations of receiver coils including:
the central receiver coil (9),
coils carried by additional walking persons at measured separation,
coils dragged behind the structure,
coils attached by booms to the front of the towing vehicle (if used),
coils attached to the support structure (19),
coils moved along independently by another vehicle, and/or
arrays of coils statically distributed over part of a survey area.

Some of these receiver coil options may use a directly connected receiver while others require synchronization of the transmitter of the embodiment to receivers via global navigation satellite system timing signals.

The measurement principle of embodiments of the present disclosures, as known by practitioners of the art, typically will be time domain (also called transient) electromagnetics. Frequency domain electromagnetics or more complex forms of electromagnetic imaging of the substrate including nuclear magnetic resonance may also be used in some embodiments.

Embodiments of the present disclosures which include a receiver coil such as the central horizontal receiver coil (8), positioned within the transmitter coil (1) require a receiver with increased dynamic range such as is now available with a time base suitable for detecting response from depths of sensitivity typical of electromagnetic prospecting systems. Such electronics is now commercially available and suitable for use in embodiments. This new development precludes the need for additional mutual inductance nulling between proximal coils such as just described.

All the booms of embodiments of the present systems and methods may be made to telescope in sections, so that:
the structure may be packed away compactly; and
lateral booms (3) may be partially retracted to facilitate survey through narrower gaps such as rows of trees in orchards.

All the booms of described embodiments may be made of rigid composite material such as:
A fibre glass and epoxy type
structure,
an aramid type fibre structure,
a mixed fibre glass and carbon fibre type structure,
an all carbon fibre type
structure, or
a natural fibre type structure
such as bamboo.

A person skilled in the art will find that any one of those construction types or compositions will be suitable starting points to make the booms as they offer rigidity, sufficient electrical resistivity to prevent inductive problems and adequate strength to weight ratio.

In an embodiment of the present disclosures, including the wheeled support vehicle, once all booms are telescoped down to minimum length and relevant connectors are disconnected, the entire structure can collapse to a substantially flat form supported by the pair of wheels (20) at one end and the towing hitch coupler (23) at the other end such that the entire structure is suited to storage when not in use and can easily be maneuvered in and out of storage and freight vehicles by a single person without any additional mechanical assistance.

In an embodiment of the present disclosures, once all booms are telescoped down to minimum length and rigid connections are disassembled the structure is suited to compact packaging without the need to remove rigging. In order to prevent tangles upon re-assembly, short elastic cords can be permanently fixed across disassembled connectors such that various booms, rods and rigging have a lesser tendency to tangle in confusing manner.

In an embodiment of the present disclosures which uses the wheeled support structure, at least one of the receiver coils (39) is supported at its centre of gravity by an intersection of two additional booms (40) extending from pivoting supports near extremities of the front of a motorized means of guided towing (38) of the embodiment and from rigging (41) passing to a high point on the said motorized means such that it moves in front of the towing means at a height above ground that reliably clears most obstacles encountered. Such a receiver coil detects ground response without significant mutual inductance with the transmitter coil such that improved detection of deeper signals is feasible. It is separated from the front of the towing means by sufficient distant such that inducted electromagnetic signal emanating from metallic parts of the towing vehicle is not substantially detected by the receiver coil (39). Said receiver coil must be supported principally at or just above its centre of gravity and only secondarily at two other points, one above each of the support boom pair. The wheelbase of said towing means should be as long as possible in order to minimize up and down movement accentuated with increasing distance in front of said vehicle.

In an embodiment of the present disclosures a receiver coil may be hand carried or towed on a sled at a fixed distance from the structure where mutual inductance with the transmitter coil is diminished.

In an embodiment of the present disclosures, a plurality of receiver coils distributed, for a period of time, on the ground while attached to receivers with global navigation satellite system timing synchronization to the transmitter of the embodiment may detect signal which is recorded as the transmitter coil passes nearby. Then the plurality of receiver coils is picked up and moved to adjacent ground and the transmitter then passes over that ground until considerable ground is covered. Such an embodiment provides numerous inductive couplings with substrate heterogeneity such that, later, three dimensional modelling can resolve the substrate at improved resolution and depth. Use of the static receivers reduces movement noise and facilitates long stacking times such that some sources of noise are reduced.

More generally, the structural components of the present disclosures comprise a moving vehicle flexibly connected to at least one structure (31) incorporating at least one coil of wire, of one or more turns, wherein coils of said are either transmitting electromagnetic signals, receiving electromagnetic signals or both transmitting and receiving electromagnetic signals. The moving vehicle contains longitudinal axes (33) for each respective said structure (31) substantially oriented in the direction of travel (37) of said vehicle, each defined by two or more collinear points of connection (32) of said respective structure to the moving vehicle, wherein the centre of gravity of each of said structures, when the orientation of said structures is not perturbed by forces of said moving vehicle over undulating terrain, is directly below the respective suspension axes a distance (34) that is small compared to the radius of gyration (34) of said structures around their respective connection axes (33) such that when said moving vehicle shakes and tilts, due to movement over rough ground, perturbation of the orientations of said coils are damped. The radius of gyration around the axis of connection may circumscribe an imaginary circle (36), beneficial for understanding the concept, in an arbitrary plane perpendicular to the axes of connection.

In an embodiment of the present disclosures, the pair of lateral boom suspenders (6) and the pair of ropes and kite blocks for lifting the lateral booms (8) are all attached to the top of the upper vertical support post (4) via a plate (44) that can pivot about an axis (43), parallel to the axis along the longitudinal boom (1) and passing through the top of the upper vertical support post (4). At rest, the attachment point (45), within the plate (4), for the pair of lateral boom suspenders (6) lies directly below pivot axis (43). When orientation of the structure (31) is perturbed then the plate (44) rotates such that attachment point (45) is pulled by weight of the structure (31) correcting its centre of gravity (42), by rotation (47) around the longitudinal boom (1), to below the points of support (32) such that the attachment point (45) tends to substantially remain above the longitudinal boom. When the orientation of structure (31) is substantially deviated from horizontal, in the plane including the lateral booms (3), then the attachment point (45) increasingly lifts the lateral boom suspenders (6), proportional to the sine of the tilt of the plate (44) until the plate is rotated almost one quadrant such that one of the pair of lateral boom suspenders approaches being collinear with a line passing through attachment point (45) and pivot point (43). In this way, when the vertical post (4) is perturbed from vertical small amounts due to forces on the roll opposing lever (7) typically resulting from travel of the structure over uneven ground while supported by a vehicle of limited width, then self-levelling will dominate orientation of the coil support structure (31) but when the structure is perturbed large amounts then it will be forced to tilt the transmitter coil (5) towards an attitude perpendicular to the upper support post (4). Should the lateral boom raising pair of ropes and kite blocks (8) also be attached to plate (44) at points in line with pivot point (43) and the points of attachment of each of the pair of ropes of (8) then simpler attachment is facilitated wherein fewer ropes need to be attached directly around the pivot point (43).

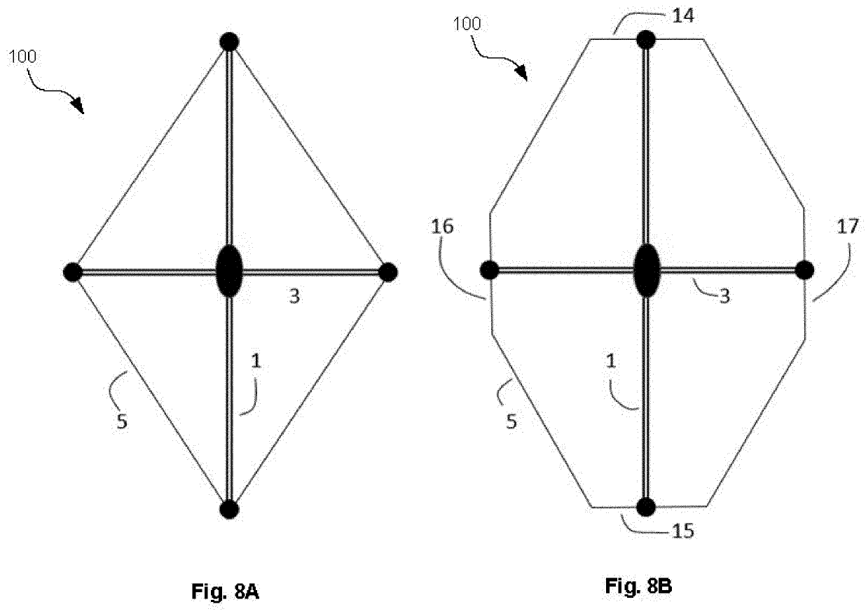

FIGS. 8A and 8B are plan views of device (100), comprising two lateral booms or otherwise referred to as second support members (3) in the first position. FIG. 8A is an embodiment that does not comprise wire mounting members (14, 15, 16, 17) and FIG. 8B is an embodiment that does comprise wire mounting members (14, 15, 16, 17). As depicted by FIG. 8A, when the second support members (3) are in the first position, wire (5) forms a substantially rhombus-like shape.

FIG. 8B shows, that when wire mounting members (14, 15, 16, 17) are disposed on the distal ends of second support members (3), connected, for example at a point that bisects the length of wire mounting members (14, 15, 16, 17), and the wire (5) is connected along substantially the length of wire mounting members (14, 15, 16, 17), the wire (5) forms a oval-like shape. In this way, the total surface area of the wire (5) may be increased, thereby offering improved sensing capabilities to the device (100). Wire mounting members (14, 15, 16, 17) may also be configured to reduce movement of the wire (5) during use of device (100), by flexing or otherwise deforming, such as in an elastic manner, to accommodate the movement of the wire (5) as the device (100) is moved over uneven and/or rugged terrain.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

### Example Clauses

To summarise the above embodiments, and without limiting the scope of, or departing from the broad general scope of the present disclosures, the following example clauses are described.

1. An electromagnetic (EM) system for measuring EM signals for the purpose of mapping the substrate, the EM system comprising:
a survey EM transmitter for generating survey EM signals;
at least one survey EM receiver for receiving and recording EM signals;
at least one global navigation satellite system (GNSS) positioning device for locating measurements; and
a moving vehicle flexibly connected to at least one loop support structure incorporating at least one coil of wire, of one or more turns, wherein said coils of said loop support structure are either transmitting electromagnetic signals, receiving electromagnetic signals or both transmitting and receiving electromagnetic signals, wherein said moving vehicle contains longitudinal axes for each respective said loop support structure substantially in the direction of travel of said vehicle, each defined by two or more substantially collinear points of connection of said respective loop support structures to the moving vehicle, wherein the centre of gravity of each of said loop support structures, when the orientation of said loop support structures is not perturbed by forces of said moving vehicle over undulating terrain, is directly below the respective suspension axes a distance that is small compared to the radius of gyration of said loop support structures around their respective connection axes such that when said moving vehicle shakes and tilts, due to movement over rough ground, perturbation of the orientations of said coils are damped.

2. The system of clause 1 wherein at least one of said loop support structures comprises:
a transmitting coil of wire, of one or more turns, which may be moved across the ground, while connected to the survey EM transmitter, wherein said coil of wire is suspended by tethering to the combination of both tips of a longitudinal boom, that is substantially horizontal oriented substantially in the direction of travel of said moving vehicle, and single tips of one or more pairs of transverse booms, opposing tips of which pivot in sockets formed in respective attachment blocks along the length of the longitudinal boom, wherein the attachment blocks also each rigidly support an upward extended, normally vertical, post with ropes extending from fixtures at their tops to attachment points equidistant and approximately midway along the lengths of the transverse booms wherein rope length is set so that those booms rest with their centre of gravity slightly lower than the centre of gravity of the longitudinal boom such that the supported coil of wire always returns to substantially horizontal orientation after any perturbation of its orientation, wherein said, normally vertical, upward extended posts are held rigidly to the respective attachment blocks which transfer rotating forces onto the longitudinal boom so that said forces may be opposed by rotational resistance at at-least one of said connection points of said longitudinal booms with said moving vehicle wherein said connection points move in unison to realise the movement of the whole structure across the ground.

3. The system of clause 2 further comprising the addition of more pairs of ropes, attached to pairs of points, on the said pairs of transverse booms, that are equidistant from the said respective attachment blocks, with each rope of said pairs passing through a kite pulley block, suspended from said fixtures at the tops of said respective upward extended posts, said rope pairs further extending on to a means of controlled pulling and releasing of said rope pairs for the purpose of upward pivoting of said transverse boom pairs, with attached parts of said transmitter coil, towards the substantially vertical plane containing the said upward extended posts and said longitudinal boom such that the whole structure can travel through narrow gaps should continuous corrective said rotational resistance be applied around said longitudinal boom such that the upward extended posts remain substantially vertical.

4. The system of clause 2 wherein said transmitter coil cross section area is further increased, being transformed from a substantially rhombic shape, inherent to fully flexible coils attached to booms as described in claim 2, to a shape more closely resembling an oval, by fixture of flexure resistant elastic rods, or tubes, along segments of said transmitter coil that are bisected by said tethering points and are attached to the boom tips via lengths of cord attached across said rod or said tube centre portions so that said rods or said tubes each hang stably in substantially horizontal attitude when not perturbed and with said transmitter coil perimeter length set so that said transmitter coil remains taut and perturbing forces result in reaction forces, that spread right around said transmitter coil, and that stabilize said transmitter coil substantially to a plane encompassing the four said tethering points and to said oval shape.

5. The system of clause 2, in which said moving connection points of said vehicle are shoulders and arms of one or more persons walking in unison such that the said persons, when connected via said loop support structure, collectively comprise said moving vehicle.

6. A method of survey adopting the system of clause 1, comprising:
a plurality of said receiver coils, connected to multiple said receivers which are recording continuously and are equipped with global navigation satellite system synchronization to said transmitter which is transmitting continuously into a transmitter coil incorporated into one said loop support structure, supported by said moving vehicle optionally equipped with an additional receiver and receiver loop;
said plurality of receiver coils are placed, and located, statically and temporarily, distributed over an area of ground to be surveyed, then said transmitter coil is passed over that area, then the receiver coils and receivers are moved to an adjacent area; and said survey process is repeated until considerable area is surveyed and a dataset suitable for improved three dimensional modelling is created.

7. The system of clause 2, wherein said moving vehicle may be comprised of: said moving connection points extending to tubes and ropes extending up from a transverse axle, encircled by two wheels of largely non-metallic construction, centred slightly in front of the centre of gravity of said coil support structure;
another boom, the drawbar, extending from near the centre of said axle to a towing device, situated in front of said coil;
at least one additional vertical tube spacing the front portion of the longitudinal boom at fixed height from the towing boom so that the coil support structure cannot tip forward or backwards nor yaw far to either side;
rigging running along each side of said drawbar attached to the towing end and to near ends of said axle so that said axle remains substantially perpendicular to the towing boom;
a means of providing guided horizontal force for moving the whole vehicle, where the means is attached to the towing end of said drawbar; and
an obstacle deflector fixed in front of said wheels to prevent square-on impact with obstacles during travel.

8. The system of clause 2 wherein said booms may be telescopic to assist in packing for freighting.

9. The system of clause 2 wherein pivoting balls fixed axially onto said pivoting ends of said pairs of lateral booms are held into said sockets by elastic cord loops fixed to said central pivoting blocks and stretched over hooks protruding from opposite sides of each said lateral boom.

10. The system of clause 2 wherein at least one of said receiver coils is of insulated multicore cable of at least one turn that is attached in the shape of a rhombus around approximately the mid points of the transverse booms and 1^{st} and 3^{rd} quartiles of the longitudinal boom wherein signal received from said receiver coil is measured with one said receiver of sufficiently high dynamic range such that high signal transients inducted through close proximity to the transmitter coil are manageable.

11. The system of clause 7 wherein at least one of said receiver coils is connected, in the said manner described by claim 1, to an intersection of two booms extending from pivoting supports near side extremities of the lower front of said means of providing guided horizontal force and from rigging passing to a high point on the said means of providing guided horizontal force.

12. The system of clause 5, further comprising, rods and rigging in said normally substantially vertical plane below said longitudinal boom such that bending forces due to the weight of the centre of the structure do not unduly bend and snap said longitudinal boom.

13. The system of clause 2, further comprising boom end hooks with spring loaded retainers that facilitate easy connection and removal of said transmitter coil.

14. The system of clause 1, wherein the bulk of structural elements substantially close to said coils are made of materials that do not substantially conduct electricity, wherein many of said materials are composite being comprised of non-metallic fibres of high tensile strength and a polymer that provides a matrix around said fibres.

15. The system of clause 2, wherein said attachment fixtures at tops of said upward extended posts are rigid plates that can pivot about axes parallel to said longitudinal booms and passing through said tops of said lateral posts, wherein ropes suspending said lateral booms from said fixtures are attached at points, on said plates, that are, when there are no perturbing forces upon said loop support structures, directly below the tops of said upward extended posts such that should said upward extended posts be temporarily perturbed from vertical a small amount then said structures will tend to self-level.

16. The system of clause 7, wherein said pair of wheels of largely non-metallic construction are comprised of pneumatic, flexible urethane donuts, with wall thickness suitable for inhibiting punctures, wherein said donuts are fixed onto rigid hubs.

17. The system of clause 1, wherein said electromagnetic signals are measured in time domain.

18. The system of clause 1, wherein said electromagnetic system is a substrate nuclear magnetic resonance detection system utilizing the magnetic field of the earth as its background field.

19. The system of clause 4, wherein said flexure resistant rods or tubes and said respective attachment point cords are affixed to said transmitter coil by glue coated poly-olefin tube that is heat shrunk over said one or more turns of wire of said transmitter coil.

20. The system of clause 7, wherein the centre of gravity of said coil support structure is sufficiently behind said axle of said moving vehicle, even when said vehicle is travelling down steep hills, so that it keeps tension on said additional vertical tubes that are spacing the front portion of said longitudinal boom at fixed separation from the towing boom such that said longitudinal boom always tends to realign parallel to said drawbar.

1. A device for measuring electromagnetic (EM) signals for mapping subsurface structures, the device comprising:
a survey EM transmitter for generating survey EM signals and/or a survey EM receiver for receiving and recording survey EM signals;
a support structure; and
a wire, mounted to the support structure, the wire configured to transmit EM signals generated by the survey EM transmitter and/or receive EM signals received by the survey EM receiver;
wherein when the device is in use, the center of gravity of the support structure is between an axis of rotation of the support structure and the ground, such that movement of the wire is substantially dampened.

2. The device of claim 1, wherein the support structure comprises:
a first support member; and
a second support member pivotably connected to the first support member;
wherein the second support member is moveable between a first position and a second position.

3. The device of claim 2, wherein:
when the device is in use and when the second support member is in the first position, the second support member is substantially parallel to the ground; and
when the second support member is in the second position, the footprint of the device is reduced.

4. The device of claim 2, wherein the wire is mounted to a distal end of the first support member and a distal end of the second support member.

5. The device of any one of claim 2, further comprising:
a third support member, mounted to the first support member, wherein when the device is in use, the third support member is orientated substantially perpendicular to the ground.

6. The device of claim 5 further comprising:
a rope, connected to the second support member and running through a pulley mounted on the third support member;
wherein the rope is configured to move the second support member from the first position to the second position.

7. The device of claim 2, comprising:
a first wire mounting member mounted to a distal end of the first support member and a second wire mounting member mounted to a distal end of the second support member, and
wherein the wire is mounted to the first flexible member and the second flexible member.

8. The device of claim 1, further comprising:
a set of wheels, the set of wheels configured to allow the device to be pulled along the ground when in use.

9. The device of claim 1, wherein the support structure comprises telescopic members.

10. The device of claim 1, wherein the device is configured to be carried by one or more human operators while in use.

11. The device of claim 8, wherein the set of wheels is mounted to a second support structure; and
wherein the second support structure is configured to be attached to a powered vehicle.

12. The device of claim 11, wherein the powered vehicle is a car or a tractor.

13. The device of claim 1, comprising a substrate nuclear magnetic resonance detection system utilizing the magnetic field of the earth as its background field.

14. The device of claim 1, further comprising a global navigation satellite system (GNSS) positioning device.

15. The device of claim 1, further comprising rigging for giving additional structural rigidity to the support structure.

16. The device of claim 1, wherein:
the wire is a first wire, and the first wire is configured to transmit survey EM signals; and
wherein the device further comprises a second wire, the second wire configured to receive EM signals induced in subsurface structures.

17. The device of claim 7, comprising:
two second support members, wherein the two second support members are pivotably connected to opposite sides of a portion of the first support member, the portion being substantially equidistant between two end points of the first support member.

18. The device of claim 17, wherein when the two second support members are in the first position, the wire forms a substantially oval-like shape.

19. The device of claim 1, wherein the wire is a cable of one or more insulated conductors, or a wire loop of one or more turns.

20. A method of mapping a substrate using the device of claim 16, the method comprising:
inducing, in a subsurface structure to be mapped, an electrical current using the EM transmitter and the first wire;
recording, using the EM receiver and the second wire, the induced electrical current in the subsurface structure to be mapped.

21. A method of a mapping a substrate using the device of claim 1, the method comprising:
positioning a receiver coil on an area of ground to be surveyed;
inducing, using the survey EM transmitter and the wire, an electrical current in a subsurface structure to be mapped;
recording, using the receiver coil and the survey EM receiver, the electrical current in the subsurface structure.
